(19) United States
(12) Patent Application Publication
(10) Pub. No.: US 2025/0072024 A1
(43) Pub. Date: Feb. 27, 2025

(54) TRANSISTOR WITH THERMAL PLUG

(71) Applicant: GlobalFoundries U.S. Inc., Malta, NY (US)

(72) Inventors: Alvin J. Joseph, Williston, VT (US); Mark D. Levy, Williston, VT (US); Rajendran Krishnasamy, Essex Junction, VT (US); Johnatan A. Kantarovsky, South Burlington, VT (US); Ajay Raman, Essex Junction, VT (US); Ian A. McCallum-Cook, Burlington, VT (US)

(21) Appl. No.: 18/237,195

(22) Filed: Aug. 23, 2023

(51) Int. Cl. H01L 29/66; H01L 29/20; H01L 29/45; H01L 29/778

(52) U.S. Cl. CPC H01L 29/66462; H01L 29/2003; H01L 29/45; H01L 29/7786

(57) ABSTRACT

The present disclosure relates to semiconductor structures and, more particularly, to a transistor with a thermal plug and methods of manufacture. The structure includes: a semiconductor substrate; a gate structure over the semiconductor substrate; a source region on a first side of the gate structure; a drain region on a second side of the gate structure; and a thermal plug extending from a top side of the semiconductor substrate into an active region of the semiconductor substrate.

This invention was made with government support under contract number HQ0727-22-9-0700 awarded by Defense Microelectronics Activity (DMEA). The government has certain rights in the invention.

### BACKGROUND

The present disclosure relates to semiconductor structures and, more particularly, to a transistor with a thermal plug and methods of manufacture.

A high-electron-mobility transistor (HEMT) is a field-effect transistor incorporating a junction between two materials with different band gaps as the channel instead of a doped region (as is generally the case for a MOSFET). A commonly used material combination is GaN with AlGaN, although there are other material variations dependent on the application of the device. HEMTs incorporating gallium nitride, for example, provide high-power performance.

HEMTs are able to operate at higher frequencies than ordinary transistors, up to millimeter wave frequencies. Accordingly, HEMTs are used in high-frequency products such as cell phones, satellite receivers, voltage converters, and radar equipment. The HEMT can also be used in low power applications such as low power amplifiers.

### SUMMARY

In an aspect of the disclosure, a structure comprises: a semiconductor substrate; a gate structure over the semiconductor substrate; a source region on a first side of the gate structure; a drain region on a second side of the gate structure; and a thermal plug extending from a top side of the semiconductor substrate into an active region of the semiconductor substrate.

In an aspect of the disclosure, a structure comprises: a semiconductor substrate comprising a plurality of semiconductor materials; a barrier layer over the plurality of semiconductor materials; a gate structure over the semiconductor substrate; at least one active regions adjacent to the gate structure; and a thermal plug extending from a top side into the at least one active region adjacent to the gate structure.

In an aspect of the disclosure, a method comprises: forming a semiconductor substrate; forming a gate structure over the semiconductor substrate; forming a source region on a first side of the gate structure; forming a drain region on a second side of the gate structure; and forming a thermal plug extending from a top side of the semiconductor substrate into an active region of the semiconductor substrate

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows a device with a thermal plug, amongst other features, and respective fabrication processes in accordance with aspects of the present disclosure.

FIG. 2 shows a device with a thermal plug in accordance with additional aspects of the present disclosure.

FIG. 3 shows a device with a thermal plug in accordance with further aspects of the present disclosure.

FIG. 4 shows a device with a thermal plug in accordance with yet further aspects of the present disclosure.

FIGS. 5A-5D show different thermal plugs in accordance with aspects of the present disclosure.

### DETAILED DESCRIPTION

The present disclosure relates to semiconductor structures and, more particularly, to a transistor with a thermal plug and methods of manufacture. More specifically, the present disclosure relates to a high electron mobility transistor (HEMT) with a thermal plug. Advantageously, the thermal plug helps remove dissipated heat from the device and improves electrical and reliability performance.

In more specific embodiments, a HEMT comprises a gate structure between a source region and a drain region, with a thermal plug proximate to the source region, the drain region or the gate structure, itself. The HEMT comprises, for example, a semiconductor stack including a barrier layer (e.g., AlGaN) on a channel layer (e.g., GaN), with the thermal plug extending through the barrier layer and channel layer. The semiconductor stack may further include a buffer layer (e.g., AlGaN) on a seed layer (e.g., AlN), with the barrier layer formed over the buffer layer. In embodiments, the thermal plug extends fully through the buffer layer and into the underlying semiconductor layers. The thermal plug may also extend partially through the underlying bottom semiconductor substrate.

The structure of the present disclosure can be manufactured in a number of ways using a number of different tools. In general, though, the methodologies and tools are used to form structures with dimensions in the micrometer and nanometer scale. The methodologies, i.e., technologies, employed to manufacture the structure of the present disclosure have been adopted from integrated circuit (IC) technology. For example, the structures are built on wafers and are realized in films of material patterned by photolithographic processes on the top of a wafer. In particular, the fabrication of the structure uses three basic building blocks: (i) deposition of thin films of material on a substrate, (ii) applying a patterned mask on top of the films by photolithographic imaging, and (iii) etching the films selectively to the mask. In addition, precleaning processes may be used to clean etched surfaces of any contaminants, as is known in the art. Moreover, when necessary, rapid thermal anneal processes may be used to drive-in dopants or material layers as is known in the art.

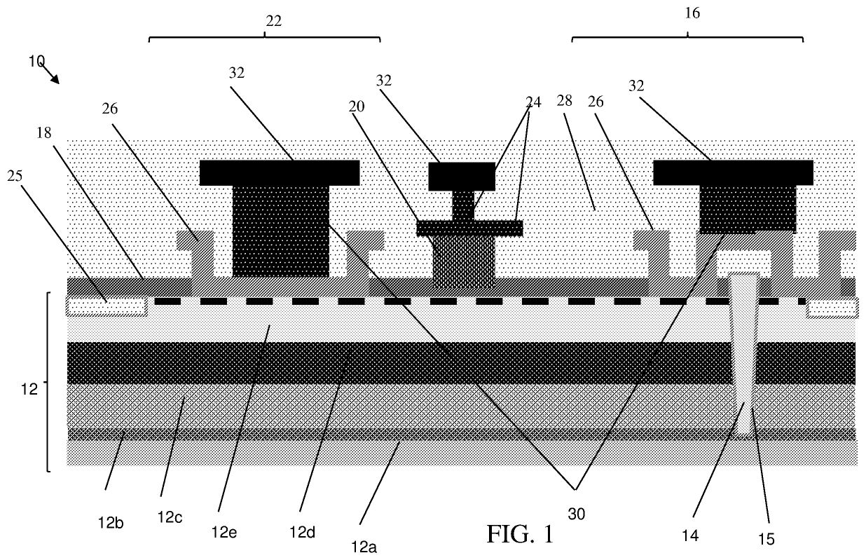

FIG. 1 shows a device with a thermal plug, amongst other features, and respective fabrication processes in accordance with aspects of the present disclosure. More specifically, the structure 10 of FIG. 1 includes a thermal plug 14, from a top side of the structure, extending through a substrate 12 in the drain region 16 (e.g., active region) of the device. The thermal plug 14 will remove dissipated heat from the device and improves electrical and reliability performance.

More specifically, the structure 10 of FIG. 1 includes a semiconductor substrate 12 with a barrier layer 18 on the semiconductor substrate 12. The semiconductor material 12 may be multiple layers of semiconductor material 12a, 12b, 12c, 12d, 12e. For example, the semiconductor substrate 12 comprises a semiconductor handle substrate 12a comprising Si; although suitable material is contemplated herein including, but not limited to, SiGe, SiGeC, SiC, GaAs, InAs, InP, and other III/V or II/VI compound semiconductors. In preferred embodiments, the semiconductor material substrate 12a may comprise a suitable crystal orientation, e.g., (111).

The semiconductor materials 12b, 12c, 12d, 12e may be formed on top of another. For example, semiconductor materials 12b may be formed on top of the semiconductor material substrate 12a, the semiconductor material 12c may be formed on top of the semiconductor material 12b, the semiconductor material 12d may be formed on top of the semiconductor material 12d, and the semiconductor material 12e may be formed on top of the semiconductor material 12d. In embodiments, the semiconductor material 12b may be a seed layer, e.g., AlN, the semiconductor material 12c may be AlN/GaN superlattice (SL), the semiconductor material 12d may be a buffer layer, e.g., GaN, and the semiconductor material 12e may be GaN which includes a two dimensional electron gas (2DEG) at the heterointerface of the barrier layer 18 as represented by the dashed line. In further embodiments, the semiconductor material 12e may be a channel region for the device. The semiconductor materials 12b, 12c, 12d, 12e may be formed by conventional epitaxial growth processes or other known deposition methods, e.g., chemical vapor deposition (CVD). The barrier layer 18 may be, for example. AlGaN.

Still referring to FIG. 1, a gate structure 20 may be provided between the drain region 16 and a source region 22 (e.g., active regions). The gate structure 20 may comprise semiconductor material formed, e.g., deposited and patterned, on the barrier layer 18. In embodiments, the semiconductor material of the gate structure 20 comprises, e.g., p-doped GaN (for an e-mode device) or a metal (a d-mode device). The semiconductor material may be epitaxially grown on the barrier layer 18 with an in-situ doping, e.g., p-type doping, as is known in the art. A metal stack 24 may be provided on top of the semiconductor material of the gate structure 20. In embodiments, the metal stack 24 may be any known gate metal stack, e.g., TiN, TiAl and/or TaN. The metal stack 24 may be deposited by a conventional deposition method (e.g., CVD), followed by conventional lithography and etching (e.g., patterning) processes.

Shallow trench isolation structures 25 may be provided at the outer edges of the drain region 16 and source region 22, and more specifically, adjacent to ohmic contacts 26 of the drain region 16 and source region 22. In alternative embodiments, other isolation structures may be used, e.g., patterned N or an Argon (Ar) implant in the areas where 2DEG is not wanted or desirable.

The shallow trench isolation structures 25 can be formed by conventional lithography, etching and deposition methods known to those of skill in the art. For example, prior to formation of the barrier layer 18, a resist formed over the semiconductor material 12e is exposed to energy (light) and developed utilizing a conventional resist developer to form a pattern (opening). An etching process with a selective chemistry, e.g., reactive ion etching (RIE), will be used to transfer the pattern from the photoresist layer to the semiconductor material 12e form one or more trenches in the semiconductor material 12e through the openings of the resist. Following the resist removal by a conventional oxygen ashing process or other known stripants, insulator material, e.g., SiO₂, can be deposited by any conventional deposition processes, e.g., chemical vapor deposition (CVD) processes. Any residual material on the surface of the semiconductor material 12e can be removed by conventional chemical mechanical polishing (CMP) processes, prior to the deposition of the barrier layer 18

Still referring to FIG. 1, the drain region 16 and source region 22 both include an ohmic contact 26. The ohmic contacts 26 directly contact the drain region 16 and the source region 20, e.g., may extend to and contact with the underlying semiconductor material 12e. The ohmic contacts 26 may be, e.g., TiAl or TiN, formed by patterning of interlevel dielectric material 28 to form trenches and/or vias and which exposes the underlying semiconductor material 12e, followed by deposition of conductive material, e.g., TiAl or TiN. In embodiments, the ohmic contacts 26 may be deposited by conventional deposition processes, e.g., chemical vapor deposition (CVD) processes.

The thermal plug 14 may be provided under the ohmic contact 26 of the drain region 16. In embodiments, the thermal plug 14 can extend through the barrier layer 18 and into the semiconductor substrate 12. In more specific embodiments, the thermal plug 14 may extend to the semiconductor material 12b, prior to contacting the semiconductor substrate 12a. In still more specific embodiments, the thermal plug 14 may extend partially into the semiconductor materials 12b. The thermal plug 14 may also extend into the interlevel dielectric material 28 above the barrier layer 18 and below the ohmic contact 26. The thermal plug 14 may be a metal material, lined with a dielectric material 15. For example, the metal plug 14 may be any conductive material with a high thermal conductivity such as Cu. The liner 15 may be, for example, a dielectric with high thermal conductance, e.g., SiO₂ or a diamond CVD. In embodiments, the thermal plug 14 is electrically isolated from the drain region 16, e.g., drain metal.

In embodiments, the thermal plug 14 may be formed by conventional lithography, etching and deposition methods known to those of skill in the art. For example, a resist formed over the barrier layer 18 is exposed to energy (light) and developed utilizing a conventional resist developer to form a pattern (opening). An etching process with a selective chemistry, e.g., RIE, will be used to transfer the pattern from the photoresist layer to the underlying semiconductor material 12a-12e form one or more trenches in the semiconductor materials 12a-12e through the openings of the resist. In embodiments, the trench may stop in the semiconductor material 12b or extend into the underlying semiconductor handle substrate 12a, depending on the particular embodiment as described herein. Following the resist removal by a conventional oxygen ashing process or other known stripants, insulator material, e.g., diamond CVD or SiO₂, can be deposited to line the trench, followed by deposition of a metal material, e.g., thermal conductive material. Any residual material on the surface of the barrier layer 18 can be removed by conventional chemical mechanical polishing (CMP) processes, prior to the formation of the ohmic contacts 26.

FIG. 1 further shows metal vias 30 directly contacting the ohmic contacts 26. In embodiments, the metal vias 30 may be composed of the same material as the gate metal 24. For example, the metal vias may be TiAl or TiN; although other materials are also contemplated herein. The metal vias 30 may be formed by conventional lithography, etching and deposition methods as is known in the art such that no further description is required for a complete understanding of the present disclosure. Wiring structures 32 may be formed in direct contact with the metal vias 30 and the gate metal 24. In embodiments, the wiring structures 32 may be, for example, copper, aluminum or other conductive material formed within the interlevel dielectric material 28.

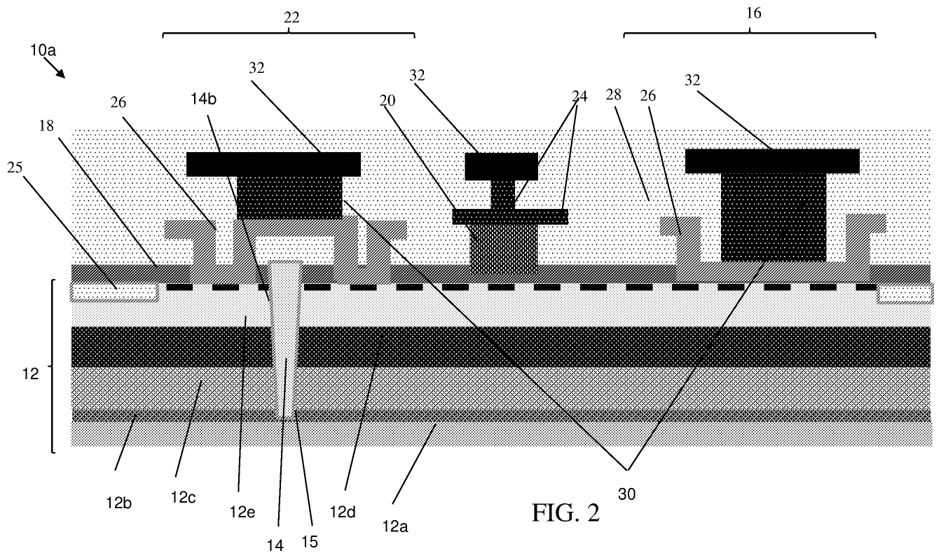

FIG. 2 shows a device with a thermal plug in accordance with additional aspects of the present disclosure. In the structure 10a of FIG. 2, the thermal plug 14 is placed under the ohmic contact 26 in the source region 22. As with the other embodiments described herein, the thermal plug 14, from a top side of the structure, may extend to the semiconductor material 12b and, in embodiments, extend partially into the semiconductor materials 12b. The thermal plug 14 may also extend into the interlevel dielectric material 28 above the barrier layer 18 and below the ohmic contact 26. The remaining features are similar to the structure 10 of FIG. 1.

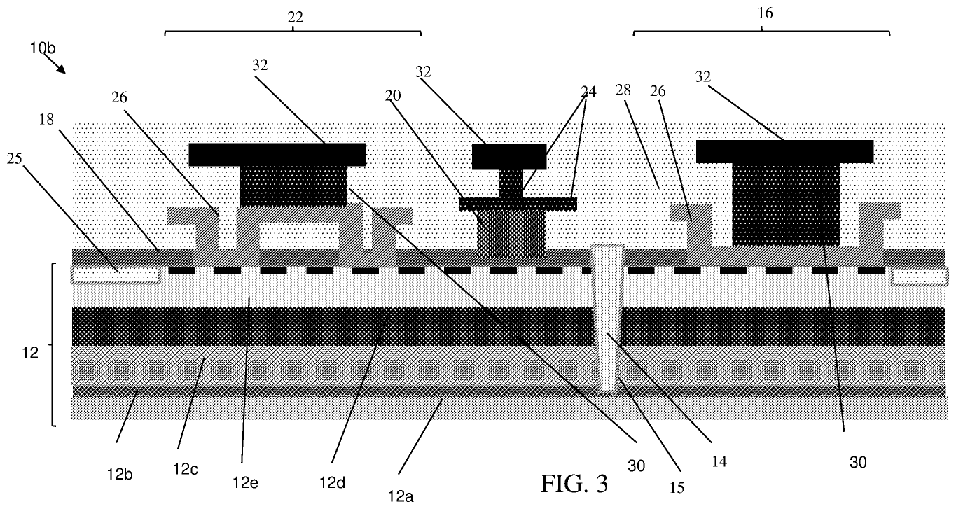

FIG. 3 shows the device with a thermal plug in accordance with additional aspects of the present disclosure. In the structure 10b of FIG. 3, the thermal plug 14 is placed between the ohmic contact 26 in the drain region 16 and the gate structure 18 (e.g., within an active region). In embodiments, the thermal plug 14 may be adjacent and closer to the gate structure 18. As with the other embodiments described herein, the thermal plug 14 may extend to the semiconductor material 12b and, in embodiments, extend partially into the semiconductor materials 12b. The thermal plug 14 may also extend into the interlevel dielectric material 28 above the barrier layer 18. The remaining features are similar to the structure 10 of FIG. 1.

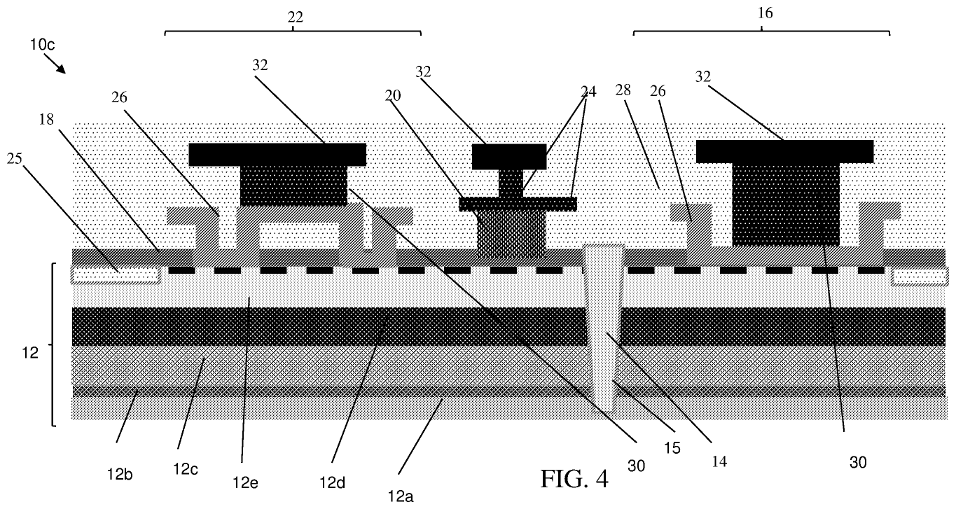

FIG. 4 shows the device with a thermal plug in accordance with yet another aspect of the present disclosure. In the structure 10c of FIG. 4, the thermal plug 14 is placed between the ohmic contact 26 in the drain region 16 and the gate structure 18, and extends into the underlying semiconductor substrate 12a. In other words, the thermal plug 14 extends into each of the semiconductor materials 12a, 12b, 12c, 12d, 12c. The thermal plug 14 may also extend into the interlevel dielectric material 28 above the barrier layer 18. The remaining features are similar to the structure 10 of FIG. 1.

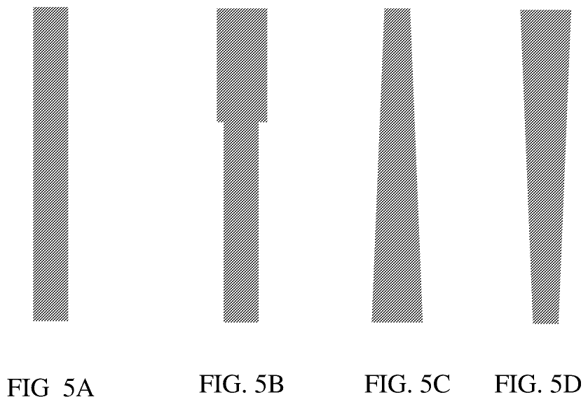

FIGS. 5A-5D show different thermal plugs in accordance with aspects of the present disclosure. For example, FIG. 5A, shows a rectangular thermal plug 14a. FIG. 5B, shows a thermal plug 14b with a step between the two rectangular portions. FIG. 5C, shows an inverted tapered thermal plug 14c; whereas FIG. 5D shows a tapered thermal plug 14d.

The HEMT can be utilized in system on chip (SoC) technology. The SoC is an integrated circuit (also known as a “chip”) that integrates all components of an electronic system on a single chip or substrate. As the components are integrated on a single substrate, SoCs consume much less power and take up much less area than multichip designs with equivalent functionality. Because of this, SoCs are becoming the dominant force in the mobile computing (such as in Smartphones) and edge computing markets. SoC is also used in embedded systems and the Internet of Things.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprising:
a semiconductor substrate;
a gate structure over the semiconductor substrate;
a source region on a first side of the gate structure;
a drain region on a second side of the gate structure; and
a thermal plug extending from a top side of the semiconductor substrate into an active region of the semiconductor substrate.

2. The structure of claim 1, further comprising ohmic contacts to the source region and the drain region.

3. The structure of claim 2, wherein the thermal plug extends under the ohmic contact in the drain region.

4. The structure of claim 2, wherein the thermal plug is electrically isolated from a drain metal.

5. The structure of claim 2, wherein the thermal plug extends under the ohmic contact in the source region.

6. The structure of claim 2, wherein the thermal plug is between the gate structure and the drain structure.

7. The structure of claim 1, wherein the thermal plug comprises a metal material lined with a dielectric material.

8. The structure of claim 1, wherein the semiconductor substrate comprises plural semiconductor materials comprising at least AlN, GaN, a superlattice material and an underlying semiconductor handle substrate.

9. The structure of claim 8, wherein the thermal plug extends, from the top side, into the underlying semiconductor handle substrate, through the AlN, the GaN and the superlattice material.

10. The structure of claim 8, wherein the thermal plug stops above the underlying semiconductor handle substrate, extending through the GaN and the superlattice material and stopping in the AlN.

11. A structure comprising:
a semiconductor substrate comprising a plurality of semiconductor materials;
a barrier layer over the plurality of semiconductor materials;
a gate structure over the semiconductor substrate;
at least one active regions adjacent to the gate structure; and
a thermal plug extending from a top side into the at least one active region adjacent to the gate structure.

12. The structure of claim 11, wherein the at least one active region comprises a drain region.

13. The structure of claim 11, wherein the at least one active region comprises a source region.

14. The structure of claim 11, wherein the at least one active region comprises a region between a drain region and the gate structure.

15. The structure of claim 11, wherein the thermal plug is a metal material lined with an insulator material.

16. The structure of claim 11, wherein the thermal plug extends through a barrier layer.

17. The structure of claim 16, wherein the thermal plug extends above the barrier layer.

18. The structure of claim 11, wherein the plurality of semiconductor materials comprises at least AlN, GaN, a superlattice material and an underlying semiconductor handle substrate, and the thermal plug extends, from the top side, into the underlying semiconductor handle substrate, through the AlN, the GaN and the superlattice material.

19. The structure of claim 11, wherein the plurality of semiconductor materials comprises at least AlN, GaN, a superlattice material and an underlying semiconductor handle substrate, and the thermal plug extends, from the top side, into the AlN, the GaN and the superlattice material, and does not contact with the underlying semiconductor handle substrate.

20. A method comprising:
forming a semiconductor substrate;
forming a gate structure over the semiconductor substrate;
forming a source region on a first side of the gate structure;
forming a drain region on a second side of the gate structure; and
forming a thermal plug extending from a top side of the semiconductor substrate into an active region of the semiconductor substrate.
